(19) United States
(12) Patent Application Publication
(10) Pub. No.: US 2011/0168475 A1
(43) Pub. Date: Jul. 14, 2011

(54) CONTROL DEVICE FOR PASSENGER PROTECTION MEANS FOR A VEHICLE AND METHOD FOR ASSEMBLING A CONTROL DEVICE FOR PASSENGER PROTECTION MEANS FOR A VEHICLE

(76) Inventors: Manfred Moser, Reutlingen (DE); Mark Wonner, Mundelsheim (DE); Roland Cupal, Markgroeningen (DE)

(21) Appl. No.: 12/736,961

(22) PCT Filed: Apr. 6, 2009
(86) PCT No.: PCT/EP2009/054064

§ 371 Date: Feb. 23, 2011

(30) Foreign Application Priority Data
Jun. 2, 2008 (DE) 10 2008 002 160.1

(51) Int. Cl. B60R 21/01; B23P 11/00; H05K 13/04

(52) U.S. Cl. 180/271; 29/428; 29/525.11; 29/825

(57) ABSTRACT

A control device for passenger protection arrangement for a vehicle includes at least one circuit board for accommodating electric components, which circuit board is disposed between a plastic lid and a plastic floor. At most three connecting arrangements are provided, which connect the plastic lid, the plastic floor, and the at least one circuit board to each other, as well as providing a force-locking connection with the vehicle body.

### BACKGROUND OF THE INVENTION

1. Field of the Invention

The present invention relates to a control device for passenger protection means for a vehicle and a corresponding method for assembling such a control device.

2. Description of Related Art

An airbag control device is known from published European patent document EP 0 927 508 B1 that has a circuit board for accommodating diverse electronic components, the circuit board being enclosed by a housing equipped with a lid. For securing the housing to the motor vehicle, the housing lid has securing tabs or flanges, via which the orientation of the control device is additionally set. This fixed orientation of the control device is necessary, since the acceleration sensor normally used has a predefined direction of sensitivity. The circuit board is secured by screws in the housing.

### BRIEF SUMMARY OF THE INVENTION

In contrast, the control device according to the present invention for passenger protection means for a vehicle and the method according to the present invention for assembling a control device for passenger protection means for a vehicle have the advantage that the circuit board is also secured by the assembly of the control device and in particular the corresponding connecting means are also used to secure the control device to the motor vehicle. Thus, an extremely cost-effective design approach is achieved that saves work steps and nevertheless results in a robust, force-locking connection between the vehicle body and the housing lid, the housing floor, and the circuit board of the control device.

In this context, it is particularly advantageous that at most three connecting means are used for the force-locking assembly of the plastic lid, the plastic floor, and the at least one circuit board. Preferably, only two are to be used, which reduces the costs even further.

Because the force-locking assembly occurs on the vehicle, it is possible to provide a pre-fixing of the plastic lid, the plastic floor, and the circuit board. This pre-fixing may be achieved by additional connecting means that are designed more simply than the at most three connecting means that are used for the force-locking assembly and for the connection with the vehicle body. Examples of this are clips and the like. However, a pre-fixing using the at most three connecting means is also possible.

The two-point or three-point fixing concept achieved in this manner allows for a sensor functionality to be guaranteed in the control device for passenger protection means. Due to the fact that the at least one circuit board is directly connected to the housing and floor via the connecting means, a transmission of oscillations and resonances or negative influence of the mechanical components is prevented. The design approach according to the related art, to initially screw in the circuit board in the airbag control device, may bring about a combination of resonances after installation in the vehicle. These resonances may have a negative effect on the transmission function, the transmission function describing the transmission of delays from the vehicle body to the circuit board and thus to the acceleration sensor.

According to the present invention, the final connection is implemented using the connecting means in the vehicle. By this means, a direct connection between the at least one circuit board and the vehicle is guaranteed. Resonances generated by mechanical components thus cannot exercise a significant influence on the circuit board.

In the case at hand, the control device is an electric device that processes sensor signals such as acceleration signals and generates control signals for the passenger protection means as a function of them. Active and passive passenger protection means are to be understood as passenger protection means. This accordingly includes passive passenger protection means such as airbags, belt tighteners, crash-active headrests, or other crash-active seat components, but also pedestrian protection means and also brakes and a driving dynamics control.

The at least one circuit board is a substrate having electric connections, on which electric and also electronic components are mounted, the electric connections connecting these electronic and electric components to each other. In this context, it is possible that an accident sensor system, such as an acceleration sensor system or a structure-borne noise sensor system, of an evaluation circuit, such as a microcontroller, and a triggering circuit for generating the triggering signals are provided on the at least one circuit board. Additional components necessary for the operation of the control device may be secured on this circuit board. The securing normally takes place through soldering or adhesive or press-in processes. A clamping joint is also possible. Thus both integral and force-locking connections of the electric components on the circuit board are possible. The circuit board may be embodied by a plastic, a ceramic, or other suitable insulating materials, metallic coatings normally acting as electric connections between the components.

However, other materials are also possible, which allow for electric connections.

According to the present invention, a plastic lid and a plastic floor are provided that enclose the circuit board, so that the at least one circuit board is disposed between the plastic lid and the plastic floor. In this context, the following materials may be used: PBT-GF30 and PA66 GF30. An admixture may possibly be provided to improve electric shielding properties, that is, for an improved electromagnetic compatibility.

For example, screws, but also rivets, clamps, or other force-locking connecting means, e.g., nuts over stay bolts, are possible as the at most three connecting means. Normally the at most three connecting means for the force-locking connection with the vehicle body must project beyond the housing floor or the housing lid in order to come into contact with the vehicle body.

The force-locking connection of the plastic lid, the plastic floor, and the at least one circuit board by the at most two connecting means is viewed as the assembly in the case at hand.

In this context, it is advantageous that the at most three connecting means are designed as screws. The most varied types of screws may be used. The screw connections are reliable and may be manufactured inexpensively.

Moreover, it is advantageous that for the at most three connecting means, sockets are provided in the plastic lid and the plastic floor, respectively. This means that the sockets for a connecting means such as a screw are provided both in the plastic lid and in the plastic floor. The threads are then located under the control device in the vehicle body. Threads may also be provided in the sockets. Thus, a reliable, force-locking screw connection is possible. This means that two sockets are provided per connecting means. The sockets may be inserted in the plastic lid and the plastic floor in various manners. One particular variant is the pressing in or the injection molding in the plastic. One advantageous variant is the injection molding in the plastic lid and the pressing in in the plastic floor.

In this context, it is possible for the socket to project beyond the housing floor. Due to the distortion and tolerances of the plastic parts, the respective socket, which is at least partially conductive and thus preferably metallic, must protrude slightly so that the earth connection may be guaranteed. This results in a flat overlay of the socket on the vehicle geometry.

The circuit board advantageously has an electric connection via at least one of the at most three connecting means. In the event that metallic screws are used as connecting means, this means that the circuit board is electrically connected via these connecting means to the vehicle body and thus has a good connection to earth. The “sandwich” socket-housing, circuit board, and socket-floor, which is implemented by the screwing, electrically connects the circuit board to the vehicle geometry (earth connection).

### BRIEF DESCRIPTION OF THE DRAWINGS

FIG. 1 shows a schematic sectional view of the control device according to the present invention.

FIG. 2 shows a detailed view of this section.

FIG. 3 shows a flow chart of the method according to the present invention.

### DETAILED DESCRIPTION OF THE INVENTION

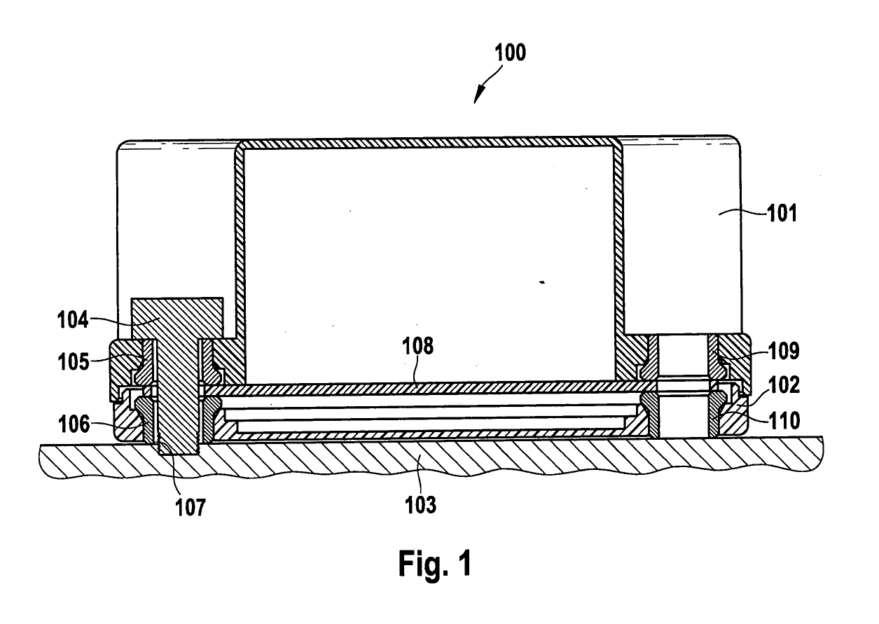

FIG. 1 illustrates in a sectional view control device 100 according to the present invention in the assembled state and connected to vehicle body 103. In the case at hand, control device 100 is connected in a force-locking manner via two socket pairs 105, 106, 109 and 110, and via screws 104 to each other and to vehicle body 103. For this purpose, the vehicle body also has corresponding threads. These may also be pressed in, for example. In the case at hand, only one screw 104 is illustrated, for example.

Screw 104 is inserted into socket 105 in plastic lid 101, through a bore hole in circuit board 108, and into an additional socket 106 of plastic floor 102, and then is screwed into the vehicle body in the respective threading. A force-locking connection of plastid lid 101, circuit board 108, and of plastic floor 102 to vehicle body 103 is thus produced. Moreover, an electric connection of circuit board 108 to vehicle body 103 and thus an earth connection may be produced either via sockets 106 and/or screws 104. The earth connection of circuit board 108 may also occur via a minimal projection 107 of the socket. The corresponding connection is implemented at the other socket pair 109 and 110, in order to use only two connecting means in the case at hand.

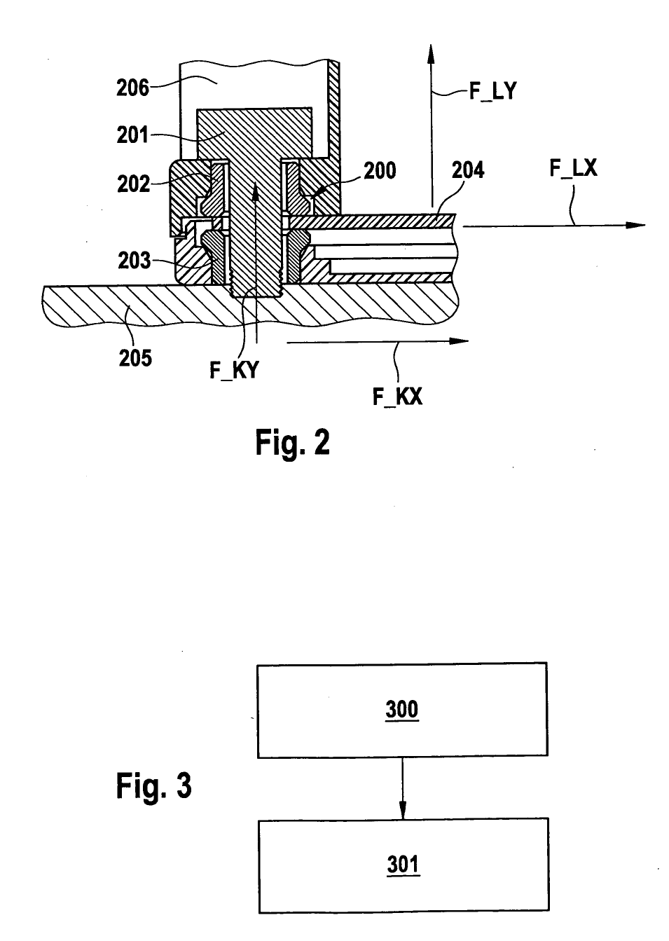

FIG. 2 illustrates in detail screw connection 200, screw 201, and the corresponding actions of force on the vehicle body and on the circuit board. Screw 201 in turn connects housing lid 206, circuit board 204, and the plastic floor with vehicle body 205. For this purpose, the screw is fed through sockets 202 in plastic lid 206 and through socket 203 in the plastic floor and screwed into the vehicle body. As shown in FIG. 2, in the vehicle body the actions of force in vehicle vertical direction F_KY and vehicle longitudinal direction F_KX are transmitted via this force-locking connection to the circuit board, so that vehicle vertical acceleration F_LY and vehicle longitudinal direction F_LX result accordingly, which then correspond to each other. This also is valid for the vehicle transverse acceleration which enters into the drawing plane.

FIG. 3 illustrates a flow chart of the method according to the present invention for assembling the control device according to the present invention. The pre-fixing of the plastic lid, the at least one circuit board, and the plastic floor occurs in method step 300 in order to then connect the prefixed control device in method step 301, to wit with at most three connecting means, a force-locking connection with the vehicle body also being provided.

1-10. (canceled)

11. A control device for passenger protection means for a vehicle, comprising:
at least one circuit board for accommodating electric components;
a plastic lid and a plastic floor, wherein the at least one circuit board is disposed between the plastic lid and the plastic floor; and
at most three connecting units providing: (a) connection of the plastic lid, the plastic floor and the at least one circuit board to each other; and (b) a force-locking connection to the vehicle body.

12. The control device as recited in claim 11, wherein the at most three connecting units are configured as screws.

13. The control device as recited in claim 12, wherein for the at most three connecting units, sockets are pressed into the plastic lid and the plastic floor.

14. The control device as recited in claim 13, wherein the at least one circuit board has an electric connection to at least one of the at most three connecting units.

15. A method for assembling a control device for a vehicle, comprising:
providing a plastic lid, a plastic floor, and at least one circuit board for accommodating electric components;
connecting, using at most three connecting units, the at least one circuit board, the plastic lid and the plastic floor to each other, wherein the at least one circuit board is disposed between the plastic lid and the plastic floor, and wherein the at most three connecting units additionally provide a force-locking connection with the vehicle body.

16. The method as recited in claim 15, wherein the at most three connecting units include screws.

17. The method as recited in claim 16, wherein for the at most three connecting units, sockets are respectively introduced into the plastic lid and the plastic floor.

18. The method as recited in claim 17, wherein the sockets are pressed into the plastic lid and the plastic floor.

19. The method as recited in claim 18, wherein an electric connection is produced between the at least one circuit board and at least one of the at most three connecting units by the connection among the plastic lid, the plastic floor, and the at least one circuit board by the at most three connecting units.
